(19) United States
(12) Patent Application Publication
(10) Pub. No.: US 2025/0072043 A1
(43) Pub. Date: Feb. 27, 2025

(54) SEMICONDUCTOR DEVICE, COMPOSITE SEMICONDUCTOR DEVICE, AND DRIVE CIRCUIT

(71) Applicant: SANKEN ELECTRIC CO., LTD., Niiza-Shi (JP)

(72) Inventor: Kenichiro TAKAHASHI, Niiza-Shi (JP)

(73) Assignee: SANKEN ELECTRIC CO., LTD., Niiza-Shi (JP)

(21) Appl. No.: 18/802,682

(22) Filed: Aug. 13, 2024

(30) Foreign Application Priority Data
Aug. 24, 2023 (JP) 2023-136135

(51) Int. Cl. H01L 29/78; H01L 27/088; H01L 29/06; H01L 29/51; H03K 17/687

(52) U.S. Cl. CPC H01L 29/7816; H01L 27/088; H01L 29/0684; H01L 29/51; H03K 17/687

(57) ABSTRACT

A semiconductor device according to one or more embodiments is disclosed that may include a p-type first semiconductor region, an n-type second semiconductor region formed on a surface of the first semiconductor region, an n-type third semiconductor region formed by separating from the second semiconductor region, an n-type fourth semiconductor region having a higher impurity concentration than the second semiconductor region, an insulating film arranged on the semiconductor substrate, a gate electrode arranged via the insulating film between the second semiconductor region and the third semiconductor region, a first main electrode electrically connected to the second semiconductor region, a second main electrode electrically connected to the fourth semiconductor region, a p-type fifth semiconductor region on the third semiconductor region, which has a higher impurity concentration than that of the first semiconductor region, and an auxiliary electrode connected to the fifth semiconductor region.

### CROSS REFERENCE TO RELATED APPLICATIONS

This application claims priority to prior Japanese Patent Application No. 2023-136135 filed with the Japan Patent Office on Aug. 24, 2023, the entire contents of which are incorporated herein by reference.

### BACKGROUND

The disclosure relates to a semiconductor device used in a drive circuit that drives a switching device or the like, a composite semiconductor device in which the semiconductor device is combined, the semiconductor device, and a drive circuit in which the composite semiconductor device is used.

### BACKGROUND ART

In order to control a load of large power such as a motor, a power semiconductor device (semiconductor device for power control) is used such as a power MOSFET or IGBT, and the control of the switching operation of the power semiconductor device is controlled by the gate voltage applied to the gate. In order to optimally control this operation, the gate voltage is controlled by a drive circuit provided separately from the power semiconductor device. The rated voltage of the power semiconductor device (for example, IGBT) is, for example, about 600V.

On the other hand, the voltage used for the control of such a power semiconductor device (gate voltage of the power semiconductor device) prevents induced noise, malfunction associated with the floating component of the LCR component, and conducts a relatively large current. For this reason, it may be assumed to have a relatively high voltage (for example, about 20V), and a drive circuit is provided for the control of the power semiconductor device.

Therefore, in general, as described in laid-open Japanese published patent application JP2004-96083 (Patent Document 1), the gate oxide film of the semiconductor device used for controlling the power semiconductor device is thickened to increase the gate breakdown voltage. However, there are many disadvantages to such a thick gate oxide film. For example, when the gate oxide film is thick, punch-through is likely to occur, so it may be necessary to increase the gate length in order to accommodate it. Alternatively, when the gate oxide film is thick, the current drive capability decreases, so it may be necessary to increase the gate width in order to compensate for it.

In addition, laid-open Japanese published patent application JPH5-308274 (Patent Document 2) discloses a drive circuit that uses a CMOS level-shifting circuit to form two types of voltages to drive a MOSFET. Further, laid-open Japanese published patent application JPH9-270699 (Patent Document 3) discloses, in the level shift circuit, a p-type semiconductor region for an intermediate tap is provided in the p-type drain region of the semiconductor device (p-channel MOSFET FIG. 3), and a circuit in which the intermediate tap is connected to the gate of the power semiconductor device. According to the circuit of Patent Document 3, the gate oxide film of the switching circuit may be thinned.

In the technique described in Patent Document 3, the potential taken out from the intermediate tap electrode is lower than the potential taken directly from the power supply voltage, but the potential taken out from the intermediate tap electrode increases according to the increase in the drain-source voltage of the MOSFET provided with the intermediate tap.

For this reason, a drive circuit or a semiconductor device used therefor have been desired which equipped with a thin gate insulating film of the semiconductor device to be driven and enables stable operation even if a relatively high voltage power supply is used.

### SUMMARY

A semiconductor device according to one or more embodiments may include a semiconductor substrate, a p-type first semiconductor region on the semiconductor substrate, an n-type second semiconductor region on the semiconductor substrate and formed on a surface of the a p-type first semiconductor region, an n-type third semiconductor region arranged on the semiconductor substrate and formed by separating from the n-type second semiconductor region, an n-type fourth semiconductor region having a higher impurity concentration than the n-type second semiconductor region arranged on the semiconductor substrate and on a side separated from the n-type second semiconductor region in the n-type third semiconductor region, an insulating film arranged on the semiconductor substrate, a gate electrode arranged via the insulating film between the n-type second semiconductor region and the n-type third semiconductor region, a first main electrode electrically connected to the n-type second semiconductor region, a second main electrode electrically connected to the n-type fourth semiconductor region, a p-type fifth semiconductor region on the n-type third semiconductor region, provided between the n-type fourth semiconductor region and the gate electrode, and having a higher impurity concentration than that of the p-type first semiconductor region; and an auxiliary electrode connected to the p-type fifth semiconductor region.

A semiconductor device according to one or more embodiments may include a semiconductor substrate, an n-type first semiconductor region on the semiconductor substrate, a p-type second semiconductor region on the semiconductor substrate and formed on a surface of the n-type first semiconductor region, a p-type third semiconductor region arranged on the semiconductor substrate and formed by separating from the p-type second semiconductor region, a p-type fourth semiconductor region having a higher impurity concentration than the p-type second semiconductor region arranged on the semiconductor substrate and on a side separated from the p-type second semiconductor region in the p-type third semiconductor region, an insulating film arranged on the p-type semiconductor substrate, a gate electrode arranged via the insulating film between the p-type second semiconductor region and the p-type third semiconductor region, a first main electrode electrically connected to the p-type second semiconductor region, a second main electrode electrically connected to the p-type fourth semiconductor region, an n-type fifth semiconductor region on the p-type third semiconductor region, provided between the p-type fourth semiconductor region and the gate electrode, and having a higher impurity concentration than that of the p-type first semiconductor region, and an auxiliary electrode connected to the n-type fifth semiconductor region.

### BRIEF DESCRIPTION OF DRAWINGS

FIG. 1 is a diagram illustrating a cross-sectional view of a first example structure of a semiconductor device according to one or more embodiments.

FIG. 2 is a diagram illustrating a cross-sectional view of a second example structure of a semiconductor device according to one or more embodiments.

FIG. 3 is a diagram illustrating a result of calculating a relationship between a drain/source voltage and an auxiliary electrode/source voltage of a first example of a semiconductor device according to one or more embodiments.

FIGS. 4A and 4B are diagrams illustrating results of calculating a potential distribution during operation in a first example of a semiconductor device according to one or more embodiments.

FIG. 5 is a diagram illustrating a result of calculating a relationship between a drain/source voltage and an auxiliary electrode/source voltage of a second example of a semiconductor device according to one or more embodiments.

FIGS. 6A and 6B are diagrams illustrating results of calculating a potential distribution during operation in a second example of a semiconductor device according to one or more embodiments.

FIG. 7 is a diagram illustrating a cross-sectional view of a structure of a first example modification of a semiconductor device according to one or more embodiments.

FIG. 8 is a diagram illustrating a first example configuration of a drive circuit according to one or more embodiments.

FIG. 9 is a diagram illustrating a symbolic correspondence between a MOSFET (n-channel type, p-channel type) and a semiconductor device (n-channel type, p-channel type) according to one or more embodiments.

FIG. 10 is a diagram illustrating a second example configuration of a drive circuit.

FIG. 11 is a diagram illustrating a second example configuration of a drive circuit according to one or more embodiments.

### DETAILED DESCRIPTION

Hereinafter, a semiconductor device according to one or more embodiments is described. The semiconductor device includes a horizontal MOSET, and both n-channel and p-channel types may be realized in the same way. A drive circuit of a power semiconductor device (drive circuit) may be constructed using such semiconductor devices, and in the drive circuit of the power semiconductor device, the gate insulating film in the next stage semiconductor device driven by the semiconductor device may be thinned and good operation may be performed.

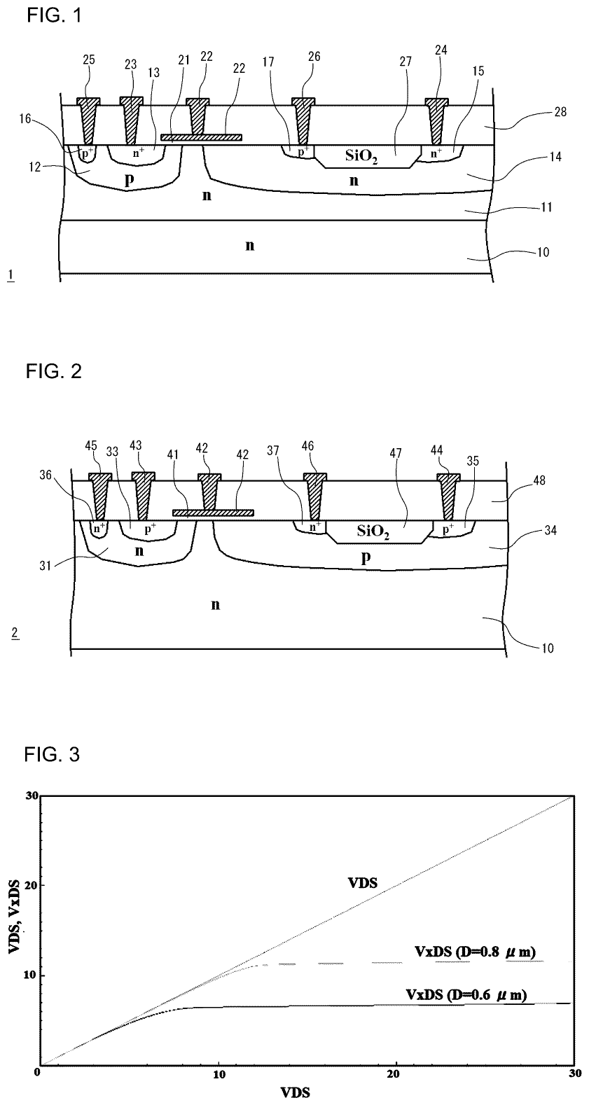

FIG. 1 is a cross-sectional view schematically illustrates the structure of the n-channel semiconductor device 1 according to one or more embodiments. Here, portions related to one or more embodiments are described, and other portions are omitted or simplified. Only the upper structure of the n-type layer (for example, an n-type layer 10), which is an epitaxial layer in a semiconductor substrate (for example, a silicon substrate), is shown.

A low concentration n-type layer (for example, n-type layer 11) of the n-channel MOSFET is formed on the surface of the n-type layer 10. Note that the n-type layer 11 may be a low concentration p-type layer rather than a low concentration n-type layer.

A low concentration p-type layer (for example, an p-type layer 12: first semiconductor region) that serves as the body layer of the n-channel MOSFET is formed on the surface of the n-type layer 11. On the surface of the p-type layer 12, a highly concentrated n-type layer (for example, an n+layer 13: second semiconductor region) that serves as a source region is formed, and an n-type layer (for example, n-type layer 14: third semiconductor region) that serves as a drain region and a drift region is formed by separating from n+layer 13 on the surface of the n-type layer 11. On the surface of the p-type layer 12 between the n+layer 13 and the n-type layer 14, the gate electrode 22 is formed via a thin gate insulating film (silicon oxide film: insulating film) 21. A source electrode (first main electrode) 23 is connected to the n+layer 13, and a drain electrode (second main electrode) 24 is formed via an n+layer 15 (fourth semiconductor region) in which n+layer 15 (fourth semiconductor region) is made into a locally highly concentrated n-type layer for contact at a place sufficiently separated from the gate electrode 22 in the horizontal direction. Further, a body electrode 25 is also formed on the surface of the p-type layer 12 via a p+layer 16 which is locally concentrated as a highly concentrated p-type layer for contact.

In the above structure, when a voltage is applied between the drain electrode 24 and the source electrode 23, the current flowing between the drain electrode 24 and the source electrode 23 is controlled by controlling the voltage between the gate electrode 22 and the source electrode 23. Here, current control may include at least one of flowing current (on) and stopping current (off). The order of the control of flowing current or stopping current may be operated first. Current control may include that the current is first flowed and then stopped. Further, current control includes the case where the current is first stopped and then the current flows.

Here, in the n-channel circuit 1, a p+layer (for example, a fifth semiconductor region) 17 is formed on the surface of an n-type layer 14 between the drain electrode 24 (for example, n+layer 15) and the end of the gate electrode 22 or the end of n-type layer 14 on the side of the gate electrode 22, An auxiliary electrode 26 is connected to the p+layer 17. Further, on the surface of the n-type layer 14 between the n+layer 15 and the p+layer 17, an embedded oxide film layer 27 formed of a LOCOS (local oxidation of silicon) oxide film or the like is formed in order to perform electrical separation between them. Further, an insulating layer 28 is formed in a portion other than the point where the electrode is located on the surface of the semiconductor substrate.

FIG. 2 is a cross-sectional view schematically showing the structure of the p-channel circuit 2, which is another example of a semiconductor device according to one or more embodiments. In this structure, an n-type layer 31 (first semiconductor region) is provided in the n-type layer 10, which is a low concentration n-type layer that is the same epitaxial layer as described above. A p+layer (second semiconductor region) 33 and an n+layer 36 are arranged on the n-type layer 31 at a distance from the p+layer 33. A p+layer (fourth semiconductor region) 35 are provided in a p-type layer (third semiconductor region) 34 that serves as a drift region and the p-type layer 34. On the surface between the p+layer 33 and the p-type layer 34, the gate electrode 42 is formed via a thin gate insulating film (silicon oxide film: insulating film) 41. A source electrode (first main electrode) 43 is electrically connected to the p+layer 33. In the horizontal direction, the p+layer 35 (fourth semiconductor region) is arranged inside the p-type layer 34 for contact at a place sufficiently separated from the gate electrode 42. The p+layer 35 may include a locally high concentration of a p-type layer. A drain electrode (second main electrode) 44 is arranged via the p+ layer 35. Further, a body electrode 45 is also formed on the surface of the n-type layer 31 via the n+layer 36 that is locally highly concentrated n-type layer for contact. The n+layer 36 may include a locally high concentration of an n-type layer. Further, an n+layer (fifth semiconductor region) 37 is a drain electrode 44 (p+layer 35) arranged closer to the p+layer 33 than to the p+layer 35 in the p-type layer 34, and the gate electrode 42 or the end of the p-type layer 34 on the side of the gate electrode 42. An auxiliary electrode 46 is connected to the n+ layer 37. Note that the n-type layer 10 may be a low concentration p-type layer rather than a low concentration n-type layer.

In FIGS. 1 and 2, the n-channel circuit 1 and the p-channel circuit 2 are shown, respectively. However, the n-channel circuit 1 and the p-channel circuit 2 may be composite semiconductor devices formed on a common semiconductor substrate having the n-type layer 10. For example, by connecting the drain electrode 24 of FIG. 1 and the drain electrode 44 of FIG. 2, it may be used like CMOS. The gate insulating film 21 and the gate insulating film 41 may be formed at the same process.

Details of the structure and operation of the n-channel circuit 1 of FIG. 1 will be described.

The concentration of impurities in the n-type layer 14, which is the drift region, may be about 5×10¹⁶ to 5×10¹⁷ cm⁻³ as a concentration that is easily depleted in order to ensure the breakdown voltage when it is turned off while ensuring conductivity with relatively low on-resistance when it is turned on. On the other hand, the impurity concentration of the p+layer 17 is sufficiently higher and may be 1×10¹⁹ to 1×10²⁰ cm⁻³, so that the p+layer 17 is not depleted even when the n-type layer 14 is depleted. When the voltage between the drain electrode 24 and the source electrode 23 is gradually increased when it is turned off, the depletion-type layer gradually expands from the p-n junction interface between the n-type layer 11 and the p-type layer 12. When the voltage between the drain electrode 24 and the source electrode 23 is further increased, the depletion-type layer reaches the p+layer 17, and when the voltage is further increased, the depletion-type layer in the n-type layer 14 is further expanded. However, since the potential in the p+layer 17 does not reach complete depletion, the potential of the p+layer 17 is saturated. Therefore, the increase in the potential of the auxiliary electrode 26 is suppressed compared to the increase in the potential of the drain electrode 24.

The saturation potential of the auxiliary electrode 26 depends on the distance in the lateral direction from the p-n junction interface where the depletion-type layer illustrated in FIG. 1 begins to expand to the p+layer 17, and the longer the distance, the larger the saturation potential. If the auxiliary electrode 26 is connected to the gate of the gate-driven switching circuit driven by the n-channel circuit 1, the voltage applied to the gate of the switching circuit may be lowered even if the applied voltage of the n-channel circuit 1 is relatively high. As a result, the gate insulating film of the switching circuit may be thinned.

Further, details of the structure and operation of the p-channel circuit 2 of FIG. 2 will be described. The concentration of impurities in the p-type layer 34, which is the drift region, may be about 5×10¹⁶ to 5×10¹⁷ cm⁻³ as a concentration that is easily depleted in order to ensure a breakdown voltage when it is turned off while ensuring conductivity with relatively low on-resistance when it is turned on. On the other hand, the impurity concentration of the n+layer 37 is sufficiently higher and may be about 1×10¹⁹ to 1×10²⁰ cm⁻³ so that the n+layer 37 is not depleted even when the p-type layer 34 is depleted. When the voltage between the drain electrode 44 and the source electrode 43 is gradually increased when it is turned off, the depletion-type layer gradually expands from the p-n junction interface between the n-type layer 10 and the p-type layer 34. When the voltage between the drain electrode 44 and the source electrode 43 is further increased, the depletion-type layer reaches the n+layer 37. When the voltage between the drain electrode 44 and the source electrode 43 is further increased, the depletion-type layer in the p-type layer 34 is further expanded, but the n+layer 37 does not reach complete depletion, and the potential of the n+layer 37 is saturated. Therefore, the increase in the potential of the auxiliary electrode 46 is suppressed compared to the increase in the potential of the drain electrode 44.

The saturation potential of the auxiliary electrode 46 depends on the lateral distance between the p n junction interface where the depletion-type layer in FIG. 2 begins to expand and the n+layer 37, and the longer the distance, the greater the saturation potential. That is, if the auxiliary electrode 46 is connected to the gate of the gate-driven switching circuit driven by the p-channel circuit 2, even if the applied voltage of the p-channel circuit 2 is relatively high, the voltage applied to the gate of the switching circuit may be lowered. As a result, the gate insulating film of the switching circuit may be thinned.

FIG. 3 shows the result of calculating the relationship between the drain and source voltage VDS and the auxiliary electrode and source voltage V×DS by simulation. In FIG. 3, the n-channel circuit 1 of FIG. 1 used in the simulation has a gate oxide film thickness of 20 nm, and the impurity concentrations of the n-type layer 11, the p-type layer 12, the n-type layer 14, and the p+layer 17 are set to 1×10¹⁵ cm⁻³, 1×10¹⁷ cm⁻³, 2×10¹⁶ cm⁻³, 1×10¹⁹ cm⁻³ respectively. In the n-channel circuit 1 of FIG. 1 used in the simulation, the depth of the n-type layer 14 and the p+layer 17 is 1.25 μm and 0.2 μm, respectively, and when the width of the p+ layer 17 is 1.1 μm and distance between the p-type layer 12 and the opposite end of the gate electrode 22 is 1.2 μm, the distance D between the p+layer 17 and the gate electrode 22 is 0.6 μm and 0.8 μm. As described above, even if VDS is increased, V×DS is saturated at a predetermined voltage, and the saturation voltage may be adjusted by the position of the p+layer 17 (the distance D between the gate electrode 22 and the p+layer 17).

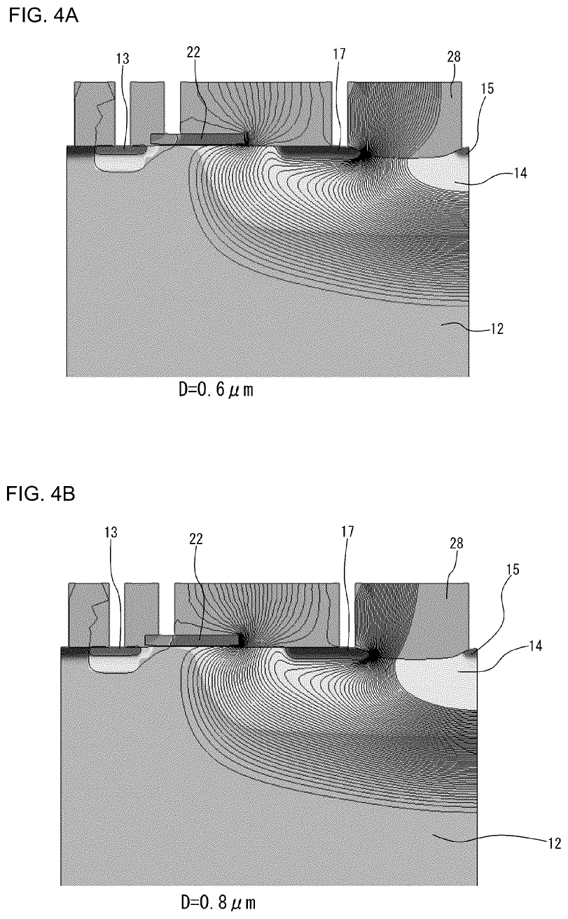

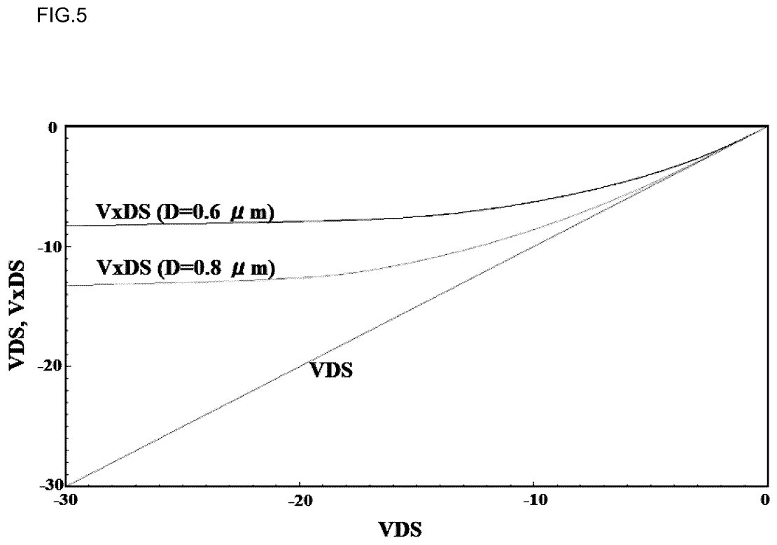

FIG. 4A shows the potential distribution when the equipotential line (0.5V interval) in the semiconductor substrate when the n-channel circuit 1 is turned off when VDS is set to 30V, and the distance D between the gate electrode 22 and the p+layer 17 is 0.6 μm, and FIG. 4B shows the result of calculating the potential distribution when the distance D is set to 0.8 μm.

As a result, it may be seen that in the above setting, the p+layer 17 is not completely depleted, and the region near the surface between the p+layer 17 and the gate electrode 22 is completely depleted. When the p+layer 17 is arranged, the electric field strength is locally increased on the surface side between the p+ layer 17 and the n+layer 15 (the side close to the p+layer 17). Therefore, as shown in FIG. 1, an embedded oxide film layer 27 may be provided. As described above, the LOCOS oxide film may be used as the embedded oxide film layer 27, but a trench oxide film in which a CVD oxide film is embedded in a groove (trench) formed by dry etching the substrate surface such as shallow trench isolation (STI) may be used.

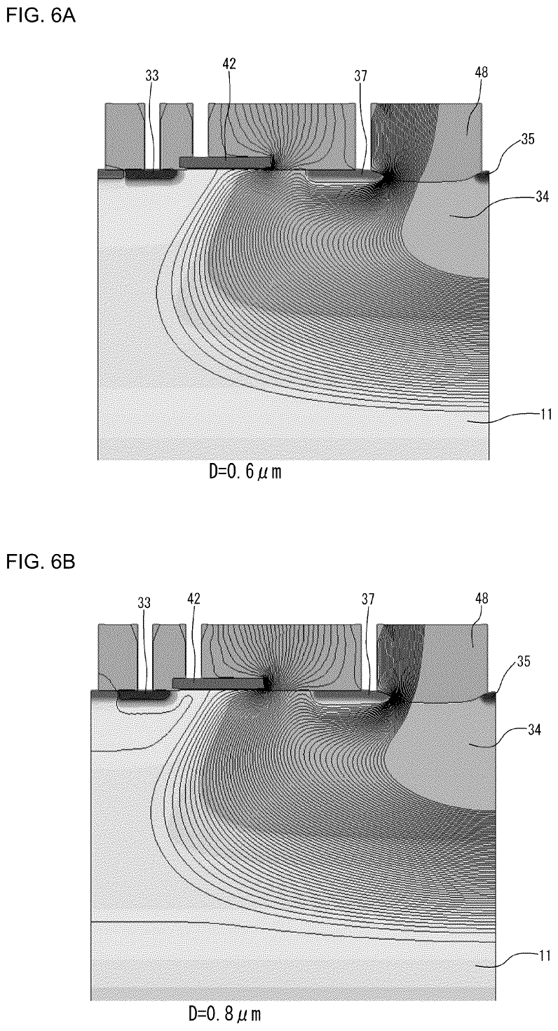

FIG. 5 is a diagram showing the characteristics of the relationship between the drain and source voltage VDS and the auxiliary electrode and source voltage V×DS in the p-channel circuit 2 shown in FIG. 2. FIGS. 6A and 6B show equipotential lines (0.5 V intervals) in the semiconductor substrate when the p-channel circuit 2 is turned off when the VDS in the p-channel circuit 2 shown in FIG. 2 is 20V. Here, the impurity concentrations of the n-type layer 10, the n-type layer 31, the p-type layer 34, and the n+layer 37 are 1×10¹⁵ cm⁻³, 1×10¹⁷ cm⁻³, 2×10¹⁶ cm⁻³, 1×10¹⁹ cm⁻³ respectively, the gate oxide film thickness is 20 nm, the depth of the p-type layer 34 is 2.2 μm, and the width of the n+layer 37 is 1.1 μm. FIG. 6A shows a case where the distance D to the gate electrode 42 and the n+ layer 37 is 0.6 μm, and FIG. 6B shows a case where the distance D to the gate electrode 42 and the n+layer 37 is 0.8 μm.

From FIG. 5, even if VDS is increased, V×DS is saturated at a predetermined voltage, and the saturation voltage may be adjusted by the position of the p+layer 17 (the distance between the gate electrode 22 and the p+layer 17). Further, from FIG. 6, it may be seen that the n+layer 37 is not completely depleted, and the space between the n+layer 37 and the gate electrode 42 is completely depleted.

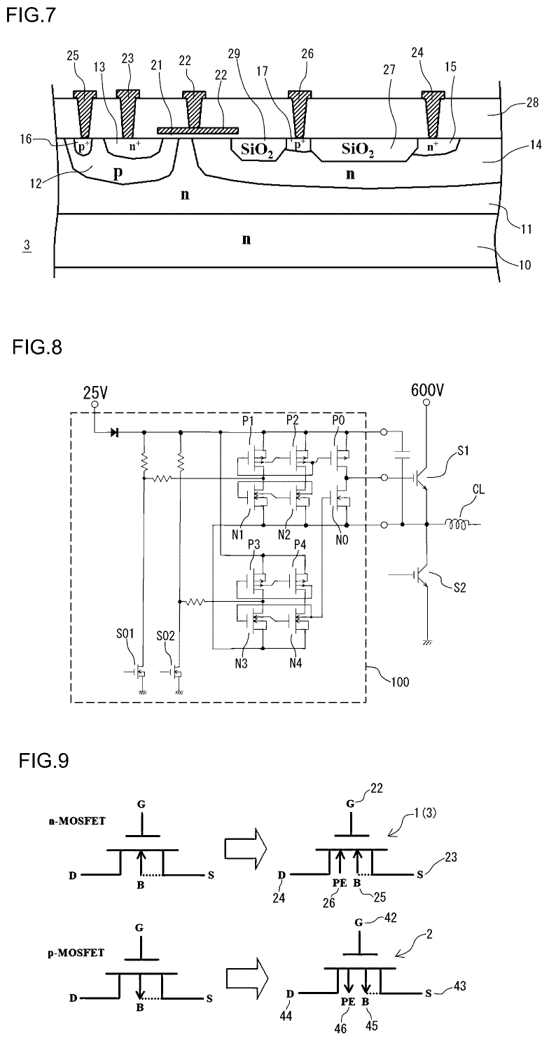

FIG. 7 is a cross-sectional view showing the structure of the n-channel circuit 3 that serves as a modification of the n-channel circuit 1. From the results of FIG. 4, the electric field strength on the surface of the n-type layer 14 between the p+layer 17 and directly below the gate electrode 22 is locally increased. For this reason, as shown in FIG. 7, an embedded oxide film layer 29 is provided on the surface of the n-type layer 14 between the p+layer 17 and directly below the gate electrode 22. The embedded oxide film layer 29 may use a LOCOS oxide film or a trench oxide film. Similarly, in the p-channel circuit 2 of FIG. 2, a LOCOS oxide film or a trench oxide film may be provided on the surface of the p-type layer 34 between the n+layer 37 and directly below the gate electrode 42.

FIG. 8 is a diagram illustrating the configuration of the drive circuit 100 of the power semiconductor device (power control circuit) in which the apparatus shown in FIGS. 1 and 2 is used. Here, power semiconductor devices (power control circuits) S1 and S2 are provided as switching circuits for controlling the operation of the coil CL. A point at which the low-voltage side of the high-side power semiconductor device S1 and the high-voltage side of the low-side power semiconductor device S1 are connected is connected to one end of the coil CL as an example of a load. Here, the power control circuit on the high side includes a power semiconductor device S1 that is a power control circuit arranged on the side of a power supply (for example, the power supply shown in the illustration 600V) for an external load (for example, coil CL). Further, the power control circuit on the low side includes a power semiconductor device S2 that is a power control circuit arranged on the ground side for an external load (for example, a coil CL).

FIG. 9 shows the symbolic correspondence between the MOSFET (n-channel, p-channel) and the n-channel circuit 1 and the p-channel circuit 2 of FIGS. 1 and 2. Here, in addition to the gate (G), the source(S), and the drain (D), the body electrode (B) is also shown, and in the n-channel circuit 1 and the p-channel circuit 2, the auxiliary electrode (PE) is further added. In FIG. 8 and the like, the symbols shown here are used.

In FIG. 8, the portion surrounded by a dashed line indicates a drive circuit, and the gate of the high-side power semiconductor device S1 is connected to a p-channel MOSFET P0 and an n-channel MOSFET NO. The gate of the p-channel MOSFET P0 is connected with the auxiliary electrode (PE) of the p-channel circuit P2. Further, the gate of the p-channel circuit P2, which is the p-channel circuit 2, is connected to the auxiliary electrode (PE) of the p-channel circuit P1, which is the p-channel circuit 2. Further, the gate of the n-channel circuit N2, which is the n-channel circuit 1, is connected to the auxiliary electrode (PE) of the n-channel circuit N1, which is the n-channel circuit 1. The gate of the n-channel circuit N1 is connected with the auxiliary electrode (PE) of the n-channel circuit N2. Since the gate connected to the auxiliary electrode (PE) is suppressed to the saturation voltage applied to the auxiliary electrode (PE), the potential of the gate connected to the auxiliary electrode (PE) may be lower than the input voltage. Thereby, a thin gate insulating film may be used in such gate. That is, the gate insulating films of the p-channel MOSFET P0, the p-channel type circuits P1 and P2, and the gate insulating films of the n-channel MOSFETs N0, n-channel circuits N1 and N2 may be uniformly thin and substantially the same thickness. Here, substantially the same thickness includes the formation of all the gate insulating films by a common oxidation process. In particular, the p-channel MOSFET P0 requires a relatively large current capacitance to transmit the gate signal of the high-side power semiconductor device (IGBT) S1, and the effect of using a thin gate insulator may be large. The same relationship as these is established between the n-channel MOSFET NO on the low side, the p-channel circuit P4 and P3 which are the p-channel circuit 2, and the n-channel circuits N4 and N3 which are the n-channel circuit 1.

A modification of the power semiconductor device drive circuit (drive circuit) 100 will be described. The effect of one or more embodiments may be obtained even if one of the MOSFETs (p-channel MOSFET P0, p-channel type circuits P1, P2) constituting the CMOS is changed to a resistive load. In this case, although the power consumption is large, since it is not necessary to form a p-channel MOSFET in the same chip, the manufacturing process may be simplified, and the drive circuit of the switching circuit may be made inexpensive or miniaturized.

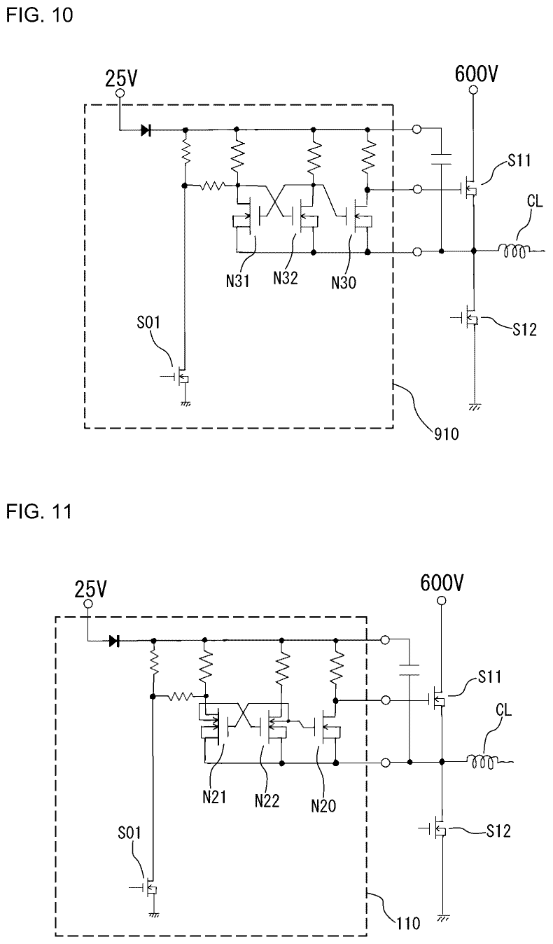

First, FIG. 10 shows the configuration of the drive circuit 910 of a power semiconductor device using a MOSFET. Here, the power semiconductor devices S11 and S12 are provided corresponding to the power semiconductor devices S1 and S2. Here, a configuration for controlling the gate voltage of the power semiconductor device S11 is shown, and a configuration for controlling the gate voltage of the power semiconductor device S12 is omitted.

A drain of the n-channel MOSFET (main switching circuit) N30 is connected to the gate of the power semiconductor device S11. The drain of the n-channel MOSFET N32 and the gate of the n-channel MOSFET N31 preceding it are connected to the gate of the n-channel MOSFET N30. Further, the gate of the n-channel MOSFET N32 is connected to the drain of the n-channel MOSFET N31. The operation of the drive circuit (electric circuit) 910 of the power semiconductor device is also controlled by the input side switching circuit S01, and the power supply voltage used is also 25V. A resistive load is provided between the power supply voltage and the n-channel MOSFETs N30, N31, and N32.

FIG. 11 shows the configuration when the power semiconductor device drive circuit (drive circuit) 110 in which the n-channel MOSFETs N31 and N32 are replaced with the n-channel circuits N21 and N22, which are the n-channel circuit 1, is used in this case. Here, the n-channel MOSFET (main switching circuit) N20 of the final output stage is a MOSFET similar to the n-channel MOSFET N30.

Here, an auxiliary electrode (PE) of the n-channel circuit N22 and a gate of the n-channel circuit N21 are connected to the gate of the n-channel MOSFET N20. Further, an auxiliary electrode (PE) of the n-channel circuit N21 is connected to the gate of the n-channel circuit N22.

Even in this configuration, since the gate voltage of the semiconductor circuit (MOSFET) to which the auxiliary electrode (PE) is connected is kept low, the gate insulating film of the circuit to which the auxiliary electrode (PE) is connected may be thinned.

In the above example, a MOS gate structure in which a silicon substrate was used as the semiconductor substrate and a silicon oxide film was used as the gate insulating film. However, even in a switching circuit using another semiconductor substrate or a switching circuit having an MIS gate structure in which another insulating film is used, the thickness of the insulating film may be reduced, and the chip may be made inexpensive, so the above configuration may be effective. Further, the power semiconductor devices S1, S2, S11, and S12 are not limited to IGBTs but may be well-known power semiconductor devices such as MOSFETs and SJ-MOSFETs.

In addition to the drive circuit of the power semiconductor device that drives the power semiconductor as described above, in an electric circuit in which a plurality of types of MOSFETs having different operating voltages are used, the above-mentioned n-channel circuit and the p-channel circuit may be used in the same way, and by combining them appropriately, the MOSFET on the side operating at a high voltage may be made to correspond to a low voltage. As a result, the chip in which this electric circuit is configured may be made inexpensive.

As described above, according to the drive circuit according to one or more embodiments, the semiconductor device and the composite semiconductor device used thereto, even if a relatively high voltage power supply is used, the gate insulating film of the semiconductor device to be driven may be thinner and stable operation may be possible.

1. A semiconductor device comprising:
a semiconductor substrate;
a p-type first semiconductor region on the semiconductor substrate;
an n-type second semiconductor region on the semiconductor substrate and formed on a surface of the p-type first semiconductor region;
an n-type third semiconductor region arranged on the semiconductor substrate and formed by separating from the n-type second semiconductor region;
an n-type fourth semiconductor region having a higher impurity concentration than the n-type second semiconductor region arranged on the semiconductor substrate and on a side separated from the n-type second semiconductor region in the n-type third semiconductor region;
an insulating film arranged on the semiconductor substrate;
a first gate electrode arranged via the insulating film between the n-type second semiconductor region and the n-type third semiconductor region;
a first main electrode electrically connected to the n-type second semiconductor region;
a second main electrode electrically connected to the n-type fourth semiconductor region;
a p-type fifth semiconductor region on the n-type third semiconductor region, provided between the n-type fourth semiconductor region and the first gate electrode; and
a first auxiliary electrode connected to the p-type fifth semiconductor region.

2. A semiconductor device comprising:
a semiconductor substrate;
an n-type first semiconductor region on the semiconductor substrate;
a p-type second semiconductor region on the semiconductor substrate and formed on a surface of the n-type first semiconductor region;
a p-type third semiconductor region arranged on the semiconductor substrate and formed by separating from the p-type second semiconductor region;
a p-type fourth semiconductor region having a higher impurity concentration than the p-type second semiconductor region arranged on the semiconductor substrate and on a side separated from the p-type second semiconductor region in the p-type third semiconductor region;
an insulating film arranged on the semiconductor substrate;
a second gate electrode arranged via the insulating film between the p-type second semiconductor region and the p-type third semiconductor region;
a third main electrode electrically connected to the p-type second semiconductor region;
a fourth main electrode electrically connected to the p-type fourth semiconductor region;
an n-type fifth semiconductor region on the p-type third semiconductor region, provided between the p-type fourth semiconductor region and the second gate electrode; and
a second auxiliary electrode connected to the n-type fifth semiconductor region.

3. The semiconductor device according to claim 1, wherein
an impurity concentration of the p-type fifth semiconductor region is higher than an impurity concentration in the n-type third semiconductor region.

4. The semiconductor device according to claim 2, wherein
an impurity concentration in the n-type fifth semiconductor region is higher than an impurity concentration in the p-type third semiconductor region.

5. The semiconductor device according to claim 1, further comprising:
a local oxidation of silicon (LOCOS) film arranged between a place to which the second main electrode is connected and the p-type fifth semiconductor region, and on the surface of the n-type third semiconductor region.

6. The semiconductor device according to claim 2, further comprising:
a local oxidation of silicon (LOCOS) film arranged between a place to which the fourth main electrode is connected and the n-type fifth semiconductor region, and on the surface of the p-type third semiconductor region.

7. The semiconductor device according to claim 1, further comprising:
a trench oxide film arranged on the surface of the n-type third semiconductor region and between a place to which the second main electrode is connected and the p-type fifth semiconductor region.

8. The semiconductor device according to claim 2, further comprising:
a trench oxide film arranged on the surface of the p-type third semiconductor region and between a place to which the fourth main electrode is connected and the n-type fifth semiconductor region.

9. A composite semiconductor device comprising:
the first semiconductor device according to claim 1; and
a second semiconductor device comprising:
an n-type first semiconductor region on the semiconductor substrate;
a p-type second semiconductor region on the semiconductor substrate and formed on a surface of the n-type first semiconductor region;
a p-type third semiconductor region arranged on the semiconductor substrate and formed by separating from the p-type second semiconductor region;
a p-type fourth semiconductor region having a higher impurity concentration than the p-type second semiconductor region arranged on the semiconductor substrate and on a side separated from the p-type second semiconductor region in the p-type third semiconductor region;
an insulating film arranged on the semiconductor substrate;
a second gate electrode arranged via the insulating film between the p-type second semiconductor region and the p-type third semiconductor region;
a third main electrode electrically connected to the p-type second semiconductor region;
a fourth main electrode electrically connected to the p-type fourth semiconductor region;
an n-type fifth semiconductor region on the p-type third semiconductor region, provided between the p-type fourth semiconductor region and the second gate electrode, and having a higher impurity concentration than that of the n-type first semiconductor region; and
a second auxiliary electrode connected to the n-type fifth semiconductor region, wherein
the second main electrode of the first semiconductor device and the fourth main electrode of the second semiconductor device are electrically connected.

10. A drive circuit comprising:
the first semiconductor device according to claim 1; and
a second semiconductor device comprising:
an n-type first semiconductor region on the semiconductor substrate;
a p-type second semiconductor region on the semiconductor substrate and formed on a surface of the n-type first semiconductor region;
a p-type third semiconductor region arranged on the semiconductor substrate and formed by separating from the p-type second semiconductor region;
a p-type fourth semiconductor region having a higher impurity concentration than the p-type second semiconductor region arranged on the semiconductor substrate and on a side separated from the p-type second semiconductor region in the p-type third semiconductor region;
an insulating film arranged on the semiconductor substrate;
a second gate electrode arranged via the insulating film between the p-type second semiconductor region and the p-type third semiconductor region;
a third main electrode electrically connected to the p-type second semiconductor region;
a fourth main electrode electrically connected to the p-type fourth semiconductor region;
an n-type fifth semiconductor region on the p-type third semiconductor region, provided between the p-type fourth semiconductor region and the second gate electrode, and having a higher impurity concentration than that of the n-type first semiconductor region; and
a second auxiliary electrode connected to the n-type fifth semiconductor region,
wherein
the first auxiliary electrode of the first semiconductor device and a first gate electrode of a first semiconductor device are electrically connected.

11. A drive circuit comprising:
the first semiconductor device according to claim 1; and
a second semiconductor device comprising:
an n-type first semiconductor region on the semiconductor substrate;
a p-type second semiconductor region on the semiconductor substrate and formed on a surface of the n-type first semiconductor region;
a p-type third semiconductor region arranged on the semiconductor substrate and formed by separating from the p-type second semiconductor region;
a p-type fourth semiconductor region having a higher impurity concentration than the p-type second semiconductor region arranged on the semiconductor substrate and on a side separated from the p-type second semiconductor region in the p-type third semiconductor region;
an insulating film arranged on the semiconductor substrate;
a second gate electrode arranged via the insulating film between the p-type second semiconductor region and the p-type third semiconductor region;
a third main electrode electrically connected to the p-type second semiconductor region;
a fourth main electrode electrically connected to the p-type fourth semiconductor region;
an n-type fifth semiconductor region on the p-type third semiconductor region, provided between the p-type fourth semiconductor region and the second gate electrode, and having a higher impurity concentration than that of the n-type first semiconductor region; and
a second auxiliary electrode connected to the n-type fifth semiconductor region, wherein
the second auxiliary electrode of the second semiconductor device and a second gate electrode of a second semiconductor device are electrically connected.

12. The drive circuit according to claim 10, further comprising:
a power control circuit that comprises a gate electrode and controls power supply to a load; and
a switching circuit that comprises a gate electrode and transmits a signal to the gate electrode of the power control circuit, wherein
the first auxiliary electrode of the first semiconductor device is electrically connected to the second-gate electrode of the switching circuit.

13. The drive circuit according to claim 11, further comprising:
a power control circuit that comprises a gate electrode and controls power supply to a load; and
a switching circuit that comprises a gate electrode and transmits a signal to the gate electrode of the power control circuit, wherein
the second auxiliary electrode of the second semiconductor device is electrically connected to the gate electrode of the switching circuit.

14. A drive circuit comprising:
the first semiconductor device according to claim 1; and
a MOS-type semiconductor device comprising a gate that is driven at a lower voltage than the first semiconductor device,
the MOS-type semiconductor device is arranged on the semiconductor substrate of the first semiconductor device,
a thickness of the insulating film of the first semiconductor device and a thickness of a gate insulating film of the MOS-type semiconductor device are substantially equal.

15. A drive circuit comprising:
the second semiconductor device according to claim 2; and
a MOS-type semiconductor device comprising a gate that is driven at a lower voltage than the second semiconductor device,
the-type semiconductor device is arranged on the semiconductor substrate of the second semiconductor device,
a thickness of the insulating film of the second semiconductor device and a thickness of a gate insulating film of the MOS-type semiconductor device are substantially equal.

16. A drive circuit comprising:
the first semiconductor device according to claim 1; and
a switching circuit that outputs a signal to a gate electrode of a first power control circuit, a gate electrode of the switching circuit is electrically connected to the first auxiliary electrode of the first semiconductor device, wherein
the drive circuit controls power supply to a load electrically connected to a point at which a low voltage side of the first power control circuit on a high side and a high voltage side of a second power control circuit on a low side are connected.

17. A drive circuit comprising:
the second semiconductor device according to claim 2; and
a switching circuit that outputs a signal to a gate electrode of a first power control circuit, a gate electrode of the switching circuit is electrically connected to the second auxiliary electrode of the second semiconductor device, wherein
the drive circuit controls power supply to a load electrically connected to a point at which a low voltage side of the first power control circuit on a high side and a high voltage side of a second power control circuit on a low side are connected.
